(19) United States
(12) Patent Application Publication
(10) Pub. No.: US 2011/0012220 A1
(43) Pub. Date: Jan. 20, 2011

(54) Wafer-level image sensor module, method of manufacturing the same and camera module

(75) Inventors: Seung Wook Park, Suwon (KR); Jing Li Yuan, Suwon (KR); Ju Pyo Hong, Suwon (KR); Si Joong Yang, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/923,454

(22) Filed: Sep. 22, 2010

Related U.S. Application Data
(62) Division of application No. 12/007,977, filed on Jan. 17, 2008.

(30) Foreign Application Priority Data
Sep. 28, 2007 (KR) 10-2007-0097803

(51) Int. Cl. H01L 31/0203

(52) U.S. Cl. 257/433; 257/E31.117

(57) ABSTRACT

A wafer-level image sensor module including: a wafer having an image sensor and a plurality of upper pads provided thereon, the wafer having an inclined surface on either side thereof; a transparent member installed above the top surface of the wafer so as to seal the image sensor; a plurality of lead portions having one ends connected to the respective upper pads, the lead portions being formed to extend to the bottom surface of the wafer along the inclined surface of the wafer; an encapsulation portion formed on the top surface of the wafer so as to be positioned outside the transparent member; and a plurality of external connection members that are electrically connected to the other ends of the respective lead portions

### CROSS-REFERENCE TO RELATED APPLICATIONS

This application is a U.S. divisional application filed under 37 USC 1.53(b) claiming priority benefit of U.S. Ser. No. 12/007,977 filed in the United States on Jan. 17, 2008, which claims earlier priority benefit to Korean Patent Application No. 10-2007-0097803 filed with the Korean Intellectual Property Office on Sep. 28, 2007, the disclosures of which are incorporated herein by reference.

### BACKGROUND

1. Field

The present invention relates to a wafer-level image sensor module, a method of manufacturing the same, and a camera module.

2. Description of the Related Art

One of main trends in a semiconductor industry is to reduce the size of semiconductor elements. In particular, a demand for the reduction in size increases in a semiconductor chip package industry. The package is formed by sealing an integrated circuit (IC) chip using plastic or ceramic resin such that the IC chip can be installed in an actual electronic device.

A conventional typical package is much large than an IC chip installed therein. Accordingly, package engineers have attempted to reduce a package size to about a chip size.

Owing to the above attempts, a chip-scale package (CSP) and a wafer-level chip-scale package (WLCSP) have been recently developed. The chip-scale package is also call ‘chip-size package’. In a conventional package manufacturing method, package assembly is performed on a separate package basis. On the other hand, in the WLCSP method, a plurality of packages are simultaneously assembled and manufactured at a wafer level.

Development of semiconductor IC chips has contributed to development of package technologies, leading to the high-density, high-speed, miniaturization and slimness of the package. The structure of a package device has evolved from a pin insert type or a through hole mount type to a surface mount type, thereby increasing the mount density for a circuit board. Recently, researches are actively conducted on a chip-size package that can reduce a package size to about a chip size while maintaining bare chip characteristics in a package state.

A WLCSP is one of chip-size packages. In the WLCSP, chip pads are rerouted or redistributed on a chip surface, and solder balls are then formed. In the WLCSP, a chip or a die is directly mounted on a circuit board by using a flip-chip method, and solder balls formed on the redistributed circuit of the chip are bonded to conductive pads of the circuit board. At this point, solder balls are also formed on the conductive pads and are thus bonded to the solder balls of the package.

Recently, there have been introduced a variety of CSP technologies that can reduce a package size to about a semiconductor chip size. These technologies are rapidly spread thanks to the miniaturization and high-integration of semiconductor devices.

A wafer-level package (WLP) technology is esteemed as the next-generation CSP technology. In the WLP technology, the entire assembly process is completed in a wafer level where chips are not diced. In the WLP technology, a series of assembly processes, such as die bonding, wire bonding, and molding, are completed in a wafer state where a plurality of chips are connected to one another, and then the resulting structure is diced to manufacture the complete products.

Therefore, compared to the CSP technology, the WLP technology can further reduce the total package costs.

In general, solder balls are formed on an active side of a semiconductor chip in the WLCSP. This structure makes it difficult to stack the WLCSP or to apply the WLCSP to the manufacturing of a sensor package such as a charge coupled device (CCD).

A conventional packaged IC device, which includes an image sensor package manufactured using the WLCSP technology, is disclosed in Korean Patent Publication No. 2002-74158. The structure of the conventional packaged IC device will be briefly described with reference to FIG. 1.

FIG. 1 illustrates an IC device provided with a microlens array 100 formed on a crystal substrate.

Referring to FIG. 1, a microlens array 100 is formed on the top surface of a crystal substrate 102. A package layer 106, which is generally formed of glass, is hermetically attached onto the bottom surface of the crystal substrate 102 through an epoxy 104. An electrical contact 108 is formed along each edge of the package layer 106. A solder ball bump 110 is formed on the bottom surface of the package layer 106, and a conductive pad 112 is formed on the top surface of the crystal substrate 102. The electrical contact 108 is connected to the solder ball bump 110 and is electrically connected to the conductive pad 112.

A package layer 114, which is generally formed of glass, and an associated spacer member 116 are hermetically attached onto the top of the crystal substrate 102 by an adhesive such as an epoxy 108 such that a cavity 120 can be formed between the microlens array 100 and the package layer 114.

The electrical contact 108 is formed, for example by plating, on the slant surfaces of the epoxy 104 and the package layer 106.

In the conventional IC device, however, the electrical contact 108 is formed to electrically connect the conductive pad 112 of the crystal substrate 102 to the bump 110. Since the IC device is manufactured through the process where the plurality of components are stacked, the structure and process of the IC device becomes complicated.

To solve such a problem, an IC device is developed, in which the microlens array 100 is provided on the crystal substrate 102 which is formed in a rectangular shape so as to connect the conductive pad 112 and the bump 110, the conductive pad 112 and the bump 110 are electrically connected through a via (not shown) which passes through the crystal substrate 102, and the package layer 114 formed of glass is installed on the crystal substrate 102 through the spacer member 116 and an adhesive such as epoxy 118 such that the entire top surface of the crystal substrate 102 is sealed.

In the IC device constructed in such a manner, however, the entire top surface of the crystal substrate 102 is covered and sealed by the package layer 114 formed of glass. Therefore, a drilling process for forming a via and a subsequent process cannot be performed using the top surface of the crystal substrate 102, but should be performed using only the bottom surface of the crystal substrate 102. Therefore, there are difficulties in performing the process.

FIG. 2 is a diagram illustrating another IC device with a different form, that is, a solid state imaging device. The solid state imaging device includes a solid state imaging chip 210, a light receiving region 220 including a microlens 230 formed on the center of the top surface of the solid state imaging chip 210, and a transparent member 240 which is formed of glass so as to seal only the light receiving region 220.

In the solid state imaging device, since the transparent member 240 is installed so as to seal only the light receiving region 220, there are no difficulty in performing a drilling process for forming a via (not shown) and so on. However, as the other region of the top surface of the solid state imaging chip 210 excluding the light receiving region 220 is exposed, reliability is degraded.

### SUMMARY

An advantage of the present invention is that it provides a wafer-level image sensor module, a method of manufacturing the same, and a camera module, in which a wiring process for external connection is easily performed to enhance productivity and reliability, and focusing does not need to be adjusted.

Additional aspects and advantages of the present general inventive concept will be set forth in part in the description which follows and, in part, will be obvious from the description, or may be learned by practice of the general inventive concept.

According to an aspect of the invention, a wafer-level image sensor module comprises a wafer; an image sensor mounted on the wafer; a transparent member installed above the top surface of the wafer so as to seal the image sensor; a plurality of vias formed in the wafer so as to be positioned outside the transparent member; a plurality of upper pads formed on the upper ends of the respective vias; an encapsulation portion formed on the top surface of the wafer so as to be positioned outside the transparent member; and a plurality of external connection members that are electrically connected to the lower ends of the respective vias.

Preferably, the transparent member is bonded to the top surface of the wafer through a bonding spacer. The bonding spacer may be formed of metal or polymer with an adhesive property.

The external connection members may be solder balls which are electrically connected to the respective vias with lower pads interposed therebetween, the lower pads being formed on the lower ends of the vias.

Each of the vias may be composed of a via hole, formed from the top surface of the wafer by a drilling process, and a conductive member filled in the via hole.

The wafer-level image sensor module further comprises an IR (Infrared) cut-off portion formed on one surface of the transparent member, the IR cut-off portion serving to cut off long-wavelength infrared light included in light incident on the image sensor. Further, the encapsulation portion may be formed of epoxy-based resin.

According to another aspect of the invention, wafer-level image sensor module comprises a wafer having an image sensor and a plurality of upper pads provided thereon, the wafer having an inclined surface on either side thereof; a transparent member installed above the top surface of the wafer so as to seal the image sensor; a plurality of lead portions having one ends connected to the respective upper pads, the lead portions being formed to extend to the bottom surface of the wafer along the inclined surface of the wafer; an encapsulation portion formed on the top surface of the wafer so as to be positioned outside the transparent member; and a plurality of external connection members that are electrically connected to the other ends of the respective lead portions.

Preferably, the transparent member is bonded to the top surface of the wafer through a bonding spacer. Further, the external connection members may be solder balls which are electrically connected to the other ends of the respective lead portions.

The image sensor module comprises an IR cut-off portion formed on one surface of the transparent member, the IR cut-off portion serving to cut off long-wavelength infrared light included in light incident on the image sensor.

Preferably, the encapsulation portion is formed of epoxy-based resin.

According to a further aspect of the invention, a method of manufacturing an image sensor module comprises the steps of: (a) mounting a plurality of image sensors on the top surface of a wafer; (b) preparing a transparent member; (c) providing the transparent member on the wafer such that the image sensors are sealed and, except for the regions of the top surface of the wafer where the image sensors are mounted, the other regions thereof are opened; (d) forming a plurality of vias in the wafer; (e) forming a plurality of encapsulation portions on the opened regions of the top surface of the wafer; and (f) dicing the wafer into a plurality of single image sensor modules.

The providing of the transparent member may include the steps of: bonding a bonding supporter to the top surface of the transparent member; removing portions of the transparent member excluding portions thereof corresponding to the regions of the wafer where the image sensors are mounted; forming a plurality of bonding spacers on any one of the wafer and the transparent member; installing the transparent member on the top surface of the wafer through the bonding spacers such that the image sensors are sealed by the transparent member; and removing the bonding supporter.

Preferably, the removing of the portions of the transparent member is performed by an etching process.

Preferably, the removing of the bonding supporter is performed by a removing process using heat, ultraviolet light; or laser.

Further, the providing of the transparent member may includes the steps of: forming grooves in portions of the bottom surface of the transparent member excluding portions thereof corresponding to the regions of the wafer where the image sensors are mounted; forming a plurality of bonding spacers on any one of the wafer and the transparent member; installing the transparent member on the top surface of the wafer through the bonding spacers such that the image sensors are sealed by the transparent member; and thinning the transparent member such that the grooves are opened upward.

Preferably, the forming of the grooves is performed by an etching process.

In the forming of the vias, a plurality of via holes may be formed from the top surface to the bottom surface of the wafer by a drilling process, and a conductive member may be filled in the respective via holes.

The method further comprises the step of forming a plurality of external connection members at the lower ends of the respective vias, wherein the forming of the external connection members is performed before the dicing of the wafer.

Preferably, the external connection members are electrically connected to the respective vias through lower pads formed on the lower ends of the vias.

The method further comprises the step of forming an IR cut-off portion on the transparent member, wherein the forming of the IR cut-off filter is performed any time before the dicing of the wafer.

According to a still further aspect of the invention, a camera module comprises a wafer-level image sensor module including: a wafer; an image sensor mounted on the wafer; transparent member installed above the top surface of the wafer so as to seal the image sensor; a plurality of vias formed in the wafer so as to be positioned outside the transparent member; a plurality of upper pads formed on the upper ends of the respective vias; an encapsulation portion formed on the top surface of the wafer so as to be positioned outside the transparent member; and a plurality of external connection members that are electrically connected to the lower ends of the respective vias; and an optical case installed on the image sensor module by coupling a lower end of the optical case to the top surface of the encapsulation portion.

Preferably, the height of the encapsulation portions is set to be smaller than that of the transparent member.

According to a still further aspect of the invention, a camera module comprises a wafer-level image sensor module including: a wafer having an image sensor and a plurality of upper pads provided thereon, the wafer having an inclined surface on each side thereof; a transparent member installed above the top surface of the wafer so as to seal the image sensor; a plurality of lead portions having one ends connected to the respective upper pads, the lead portions being formed to extend to the bottom surface of the wafer along the inclined surface of the wafer; an encapsulation portion formed on the top surface of the wafer so as to be positioned outside the transparent member; and a plurality of external connection members that are electrically connected to the other ends of the respective lead portions; and an optical case installed on the image sensor module by coupling a lower end of the optical case to upper end surface of the encapsulation portion.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 illustrates an IC device provided with a microlens array 100 formed on a crystal substrate;

FIG. 2 is a diagram illustrating another IC device with a different form, that is, a solid state imaging device;

FIG. 3 is a schematic cross-sectional view of a wafer-level image sensor module according to a first embodiment of the present invention;

FIGS. 4 to 10 are cross-sectional process views for sequentially explaining a method of manufacturing the wafer-level image sensor module according to the first embodiment of the invention;

FIGS. 11 and 17 are cross-sectional views for explaining another embodiment of the method of manufacturing the wafer-level image sensor module according to the first embodiment of the invention;

FIG. 18 is a schematic cross-sectional view of a wafer-level image sensor module according to a second embodiment of the invention; and

FIG. 19 is a schematic cross-sectional view of a camera module to which the wafer-level image sensor module according to the first embodiment of the invention is applied.

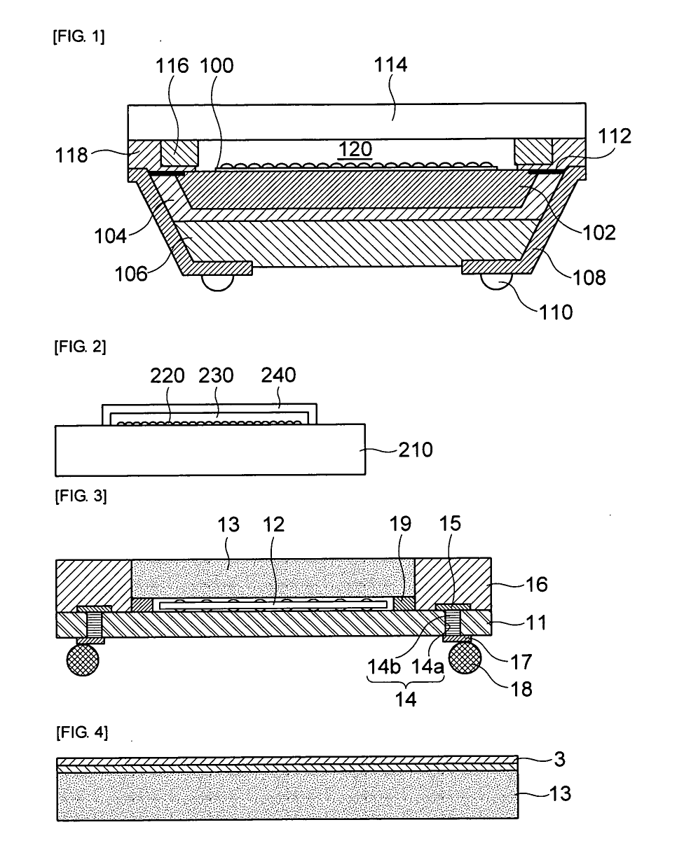

### DESCRIPTION OF EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a wafer-level image sensor module, a method of manufacturing the same, and a camera module according to the present invention will be described in detail with reference to the accompanying drawings.

### First Embodiment of Image Sensor Module

Referring to FIG. 3, a wafer-level image sensor module according to a first embodiment of the invention will be described in detail.

FIG. 3 is a schematic cross-sectional view of a wafer-level image sensor module according to a first embodiment of the invention.

As shown in FIG. 3, the wafer-level image sensor module according to the first embodiment of the invention includes a wafer 11, an image sensor 12 mounted on the top surface of the wafer 11, a transparent member 13 installed above the top surface of the wafer 11 so as to seal the image sensor 12, a plurality of vias formed in the wafer 11 so as to be positioned outside the transparent member 13, a plurality of upper pads 15 formed on the upper ends of the respective vias 14, an encapsulation portion 16 formed on the top surface of the wafer 11 so as to be positioned outside the transparent member 13, and a plurality of external connection members 18 which are electrically connected to the lower ends of the respective vias 14.

Preferably, the transparent member 13 is bonded to the top surface of the wafer 11 through a bonding spacer 19.

Therefore, the transparent member 13 is installed so as to be spaced upward from the top surface of the wafer 11 at a distance corresponding to the thickness of the bonding spacer 19.

In this case, the transparent member 13 may be formed of glass, and the bonding spacer 19 may be formed of metal or polymer with an adhesive property.

Each of the vias 14 may be composed of a via hole 14a formed from the top surface of the wafer 11 through a drilling process and a conductive member 14b filled in the via hole 14a.

In this case, the via hole 14a may be formed by a laser process instead of the drilling process, and the conductive member 14b may be a conductive metal filled in the via hole 14a.

The external connection members 18 may be solder balls which are electrically connected to the respective vias 14 with lower pads 17 interposed therebetween, the lower pads 17 being formed on the lower ends of the vias 14.

In this case, the external connection member 18 may be formed of a solder bump with a different shape, in addition to the solder ball.

Meanwhile, the wafer-level image sensor module may include an infrared light (IR) cut-off portion (not shown) provided on one surface of the transparent member 13 such that long-wavelength infrared light, included in light incident on the image sensor 12 through the transparent member 13, can be cut off.

The IR cut-off portion may be an IR cut-off coating layer, which is formed by coating one surface of the transparent member 13 with an IR cut-off material, or an IR cut-off member such as an IR cut-off filter, which is installed on one surface of the transparent member 13.

Instead of the IR cut-off portion provided in the wafer-level image sensor module, an IR cut-off member such as an IR cut-off filter may be mounted on an optical case which is coupled to the image sensor module so as to compose one camera module. Then, long-wavelength infrared light incident on the image sensor 12 can be cut off.

Preferably, the encapsulation portion 16 may be formed of epoxy-based resin.

Except for the region of the top surface of the wafer 11 sealed by the transparent member 13, the encapsulation portion 16 covers the other region of the top surface of the wafer 11. Therefore, circuit patterns such as the upper pads 15 and so on are protected, thereby enhancing reliability.

Referring to FIGS. 4 to 10, a method of manufacturing the wafer-level image sensor module according to the first embodiment of the invention will be described in detail.

FIGS. 4 to 10 are cross-sectional process views for sequentially explaining a method of manufacturing the wafer-level image sensor module according to the first embodiment of the invention.

First, as shown in FIG. 4, a transparent member 13 is prepared. In this case, a bonding supporter 3 is bonded on one surface of the transparent member 13. Then, although a portion of the transparent member 13 is removed, the other portion thereof can be fixed by the bonding supporter 3.

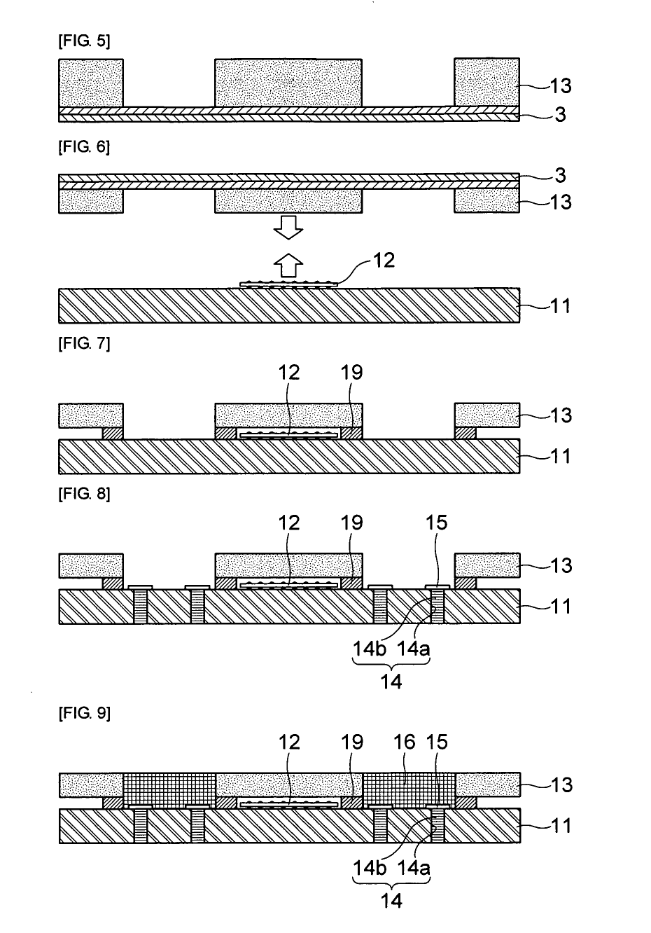

Then, except for portions of the transparent member 13 corresponding to regions of a wafer 11 where a plurality of image sensors 12 are to be mounted (refer to FIG. 6), the other portions of the transparent member 13 are removed, as shown in FIG. 5.

At this time, the removing of the portions of the transparent member 13 may be performed by an etching process.

Further, as shown in FIG. 6, the image sensors 12 are mounted on the top surface of the wafer 11, and a plurality of bonding spacers 19 are provided on any one of the wafer 11 and the transparent member 13. Then, the transparent member 13 is installed on the top surface of the wafer 11 through a plurality of bonding spacers 19 such that the image sensors 12 are sealed.

Next, after the transparent member 13 is installed on the top surface of the wafer 11, the bonding supporter 3 provided on one surface of the transparent member 13 is removed by a removing process using heat, ultraviolet light, or laser, as shown in FIG. 7.

Accordingly, except for the regions of the top surface of the wafer 11 where the image sensors 12 are sealed, the other regions of the top surface of the wafer 11 are opened.

Then, as shown in FIG. 8, a plurality of vias 14 and upper pads 15 are formed in the wafer 11.

At this time, the via 14 can formed by the following process. A plurality of via holes 14a are formed from the top surface to the bottom surface of the wafer 11 by a drilling process, and a conductive member is filled in the via holes 14b.

Then, as shown in FIG. 9, a plurality of encapsulation portions 16 are formed on the opened regions of the top surface of the wafer 11.

At this time, the encapsulation portion 16 may be formed of epoxy-based resin or the like.

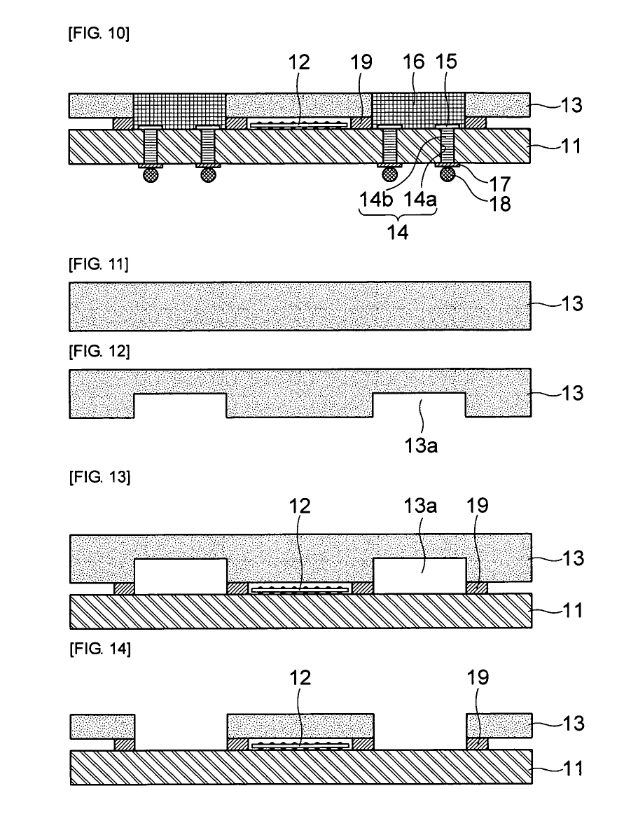

Further, as shown in FIG. 10, a plurality of external connection portions 18 are formed at the lower ends of the vias 14.

At this time, the external connection members 18 can be electrically to the vias 14 with lower pads 17 interposed therebetween, the lower pads 17 being formed on the lower ends of the vias 14.

That is, the via 14 serves to electrically connect an electrode pad such as an upper pad 15, provided on the top surface of the wafer 11, to the lower pad 17 and the external connection member 18 which are provided on the bottom surface of the wafer 11.

Meanwhile, the process of forming the external connection members 18 may be performed before the forming of the encapsulation portion 16.

After that, the wafer 11 is diced into a plurality of single image sensor modules shown in FIG. 3.

Although not shown, an IR cut-off portion is formed on the transparent member 13 such that long-wavelength infrared light incident on the image sensor 12 through the transparent member 13 can be cut off.

At this time, the process of forming the IR cut-off portion on the transparent member 13 may be performed any time, if the process is performed before the dicing of the wafer 11.

Referring to FIGS. 11 to 17, another embodiment of the method of manufacturing the wafer-level image sensor module according to the first embodiment of the invention will be described.

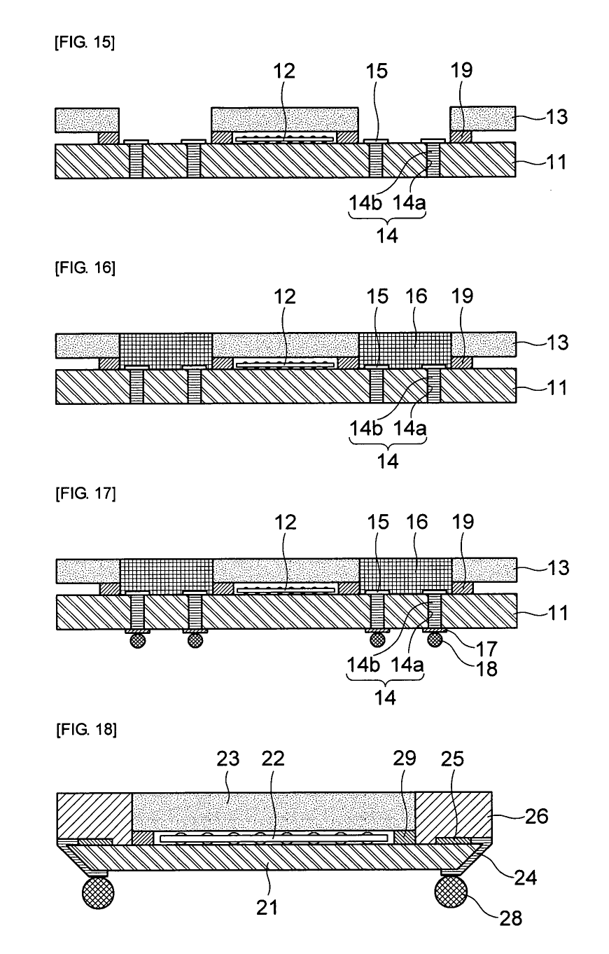

FIGS. 11 and 17 are cross-sectional views for explaining another embodiment of the method of manufacturing the wafer-level image sensor module according to the first embodiment of the invention.

First, as shown in FIG. 11, a transparent member 13 is prepared.

Then, as shown in FIG. 12, grooves 13a are formed on portions of the bottom surface of the transparent member 13, excluding portions thereof corresponding to regions of a wafer 11 where image sensors 12 are to be mounted.

At this time, the forming of the grooves 13a may be performed by an etching process.

Further, as shown in FIG. 13, the image sensors 12 are mounted on the top surface of the wafer 11, and a plurality of bonding spacers 19 are provided on any one of the wafer 11 and the transparent member 13. Then, the transparent member 13 is installed on the top surface of the wafer 11 through a plurality of bonding spacers 19 such that the image sensors 12 are sealed.

Next, after the transparent member 13 is installed on the top surface of the wafer 11, the transparent member 13 is thinned in such a manner that the grooves 13a of the transparent member 13 are opened upward, as shown in FIG. 14.

Accordingly, except for the regions of the top surface of the wafer 11 where the image sensors 12 are sealed, the other regions thereof are opened.

Then, as shown in FIG. 15, a plurality of vias 14 and upper pads 15 are formed on the wafer 11.

At this time, the vias 14 are formed by the following process. A plurality of via holes 14a are formed from the top surface to the bottom surface of the wafer 11 through a drilling process or the like, and a conductive member is then filled in the via holes 14b.

Next, as shown in FIG. 16, a plurality of encapsulation portions 16 are formed on the opened regions of the top surface of the wafer 11.

At this time, the encapsulation portion 16 may be formed of epoxy-based resin or the like.

Further, as shown in FIG. 17, a plurality of external connection members 18 are formed at the lower ends of the respective vias 14.

At this time, the external connection members 18 can be electrically connected to the vias 14 with lower pads 17 interposed therebetween, the lower pads 17 being formed on the lower ends of the vias 14.

That is, the vias 14 serve to electrically connect electrode pads such as the upper pads 15, provided on the top surface of the wafer 11, to the lower pads 17 and the external connection members 18 provided on the bottom surface of the wafer 11.

Meanwhile, the process of forming the external connection members 18 may be formed before the forming of the encapsulation portions 16.

After that, the wafer 11 is diced into a plurality of single image sensor modules shown in FIG. 3.

Although not shown, an IR cut-off portion is formed on the transparent member 13 such that long-wavelength infrared light incident on the image sensor 12 through the transparent member 13 can be cut off.

At this time, the process of forming the IR cut-off portion on the transparent member 13 may be performed any time, if the process is performed before the dicing of the wafer 11.

### Second Embodiment of Image Sensor Module

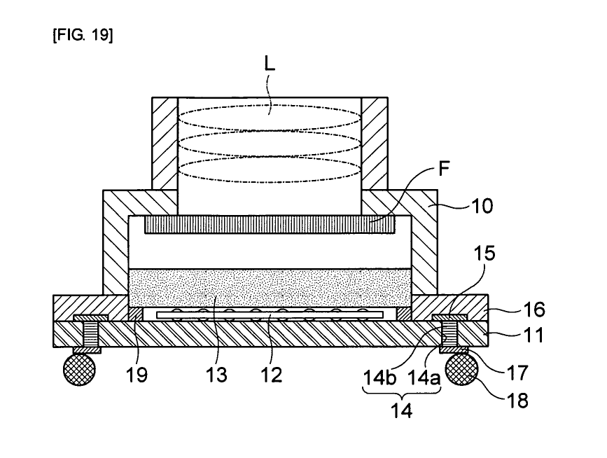

Referring to FIG. 18, a wafer-level image sensor module according to a second embodiment of the invention will be described in detail.

FIG. 18 is a schematic cross-sectional view of a wafer-level image sensor module according to a second embodiment of the invention.

As shown in FIG. 18, the image sensor module according to the second embodiment of the invention includes a wafer 21 having an image sensor 22 and a plurality of upper pads 25 provided on the top surface thereof and an inclined surface formed in each side thereof, a transparent member 23 installed above the top surface of the wafer 21 such that the image sensor 22 is sealed, a plurality of lead portions 24 having one end connected to the upper pad 25 and formed to extend to the bottom surface of the wafer 21 along the inclined surface of the wafer 21, an encapsulation portion 26 formed on the top surface of the wafer 21 so as to be positioned outside the transparent member 23, and a plurality of external connection members 28 which are electrically connected to the other ends of the lead portions 24.

Preferably, the transparent member 23 is bonded to the top surface of the wafer 21 through a bonding spacer 29.

Therefore, the transparent member 23 is installed so as to be spaced from the top surface of the wafer 21 at a distance corresponding to the thickness of the bonding spacer 29.

At this time, the transparent member 23 may be formed of glass, and the bonding spacer 29 may be formed of metal or polymer with an adhesive property.

The external connection members 28 may solder balls which are electrically connected to the other ends of the respective lead portions 24.

In this case, the external connection member 28 may be formed of a solder bump with a different shape, in addition to the solder ball.

Meanwhile, the wafer-level image sensor module has an IR cut-off portion (not shown) provided on one surface of the transparent member 23 such that long-wavelength infrared light, included light incident on the image sensor 22 through the transparent member 23, can be cut off by the IR cut-off portion.

In this case, the IR cut-off portion may be an IR cut-off coating layer, which is formed by coating one surface of the transparent member 23 with an IR cut-off material, or an IR cut-off member such as an IR cut-off filter, which is installed on one surface of the transparent member 23.

Instead of the IR cut-off portion provided in the wafer-level image sensor module, an IR cut-off member such as an IR cut-off filter may be mounted on an optical case which is coupled to the image sensor module so as to compose one camera module. Then, long-wavelength infrared light incident on the image sensor 22 can be cut off.

Preferably, the encapsulation portion 26 may be formed of epoxy-based resin.

As the encapsulation portion 26 is formed so as to cover the other region of the top surface of the wafer 21 excluding the region thereof sealed by the transparent member 23, circuit patterns such as the upper pads 25 and so on are protected, thereby enhancing reliability.

### Camera Module

Referring to FIG. 19, a camera module to which a wafer-level image sensor module according to the invention is applied will be described in detail.

FIG. 19 is a schematic cross-sectional view of a camera module to which the wafer-level image sensor module according to the first embodiment of the invention is applied.

As shown in FIG. 19, the camera module includes the image sensor module according to the first embodiment of the invention and an optical case 10 of which the lower end is coupled to the top surface of the encapsulation portion 16 composing the image sensor module.

In this case, the encapsulation portion 16 may be formed with a height smaller than that of the transparent member 13 including the bonding spacer 19.

As the lower end of the optical case 10 is directly coupled to the top surface of the encapsulation portion 16, the height of the encapsulation portions 16 can be adjusted so as to reduce the thickness of the camera module. Further, a focal distance between the image sensor 12 and a lens L mounted in the optical case 10 is constantly maintained, which makes it possible to implement a camera module in which focusing does not need to be adjusted.

In the camera module shown in FIG. 19, an IR cut-off filter F for cutting off long-wavelength infrared light, included in light incident on the image sensor 12 through the transparent member 13, is mounted on the optical case 10. However, the IR cut-off portion may be formed on one surface of the transparent member 13, as described above. Then, the space of the optical case 10, where the IR cut-off filter F is installed, can be removed so as to further reduce the thickness of the camera module.

Further, in a camera module to which the image sensor module according to the second embodiment of the invention is applied, the lower end of the optical case 10 is also directly coupled to the top surface of the encapsulation portion. Further, the encapsulation portion is formed with a height smaller than the transparent member including the bonding spacer. Therefore, it is possible to reduce the thickness of the camera module and to implement a camera module in which focusing does not need to be adjusted.

According to the present invention, the wiring process for external connection can be easily performed, thereby enhancing productivity.

Further, except for the region of the top surface of the wafer where the image sensor is mounted, the other region can be protected during the package process. Therefore, it is possible to enhance reliability.

Further, at a wafer-level state, the transparent member is installed and the encapsulation portion is formed, which makes it possible to minimize defects caused by foreign matters.

Furthermore, as the lower end of the optical case is directly coupled to the upper end surface of the encapsulation portion, the height of the encapsulation portion is adjusted, which makes it possible to reduce the thickness of the camera module. Further, a focal distance between the image sensor and the lens mounted on the optical case is constantly maintained, which makes it possible to implement a camera module in which focusing does not need to be adjusted.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A wafer-level image sensor module comprising:
a wafer having an image sensor and a plurality of upper pads provided thereon, the wafer having an inclined surface on either side thereof;
a transparent member installed above the top surface of the wafer so as to seal the image sensor;
a plurality of lead portions having one ends connected to the respective upper pads, the lead portions being formed to extend to the bottom surface of the wafer along the inclined surface of the wafer;
an encapsulation portion formed on the top surface of the wafer so as to be positioned outside the transparent member; and
a plurality of external connection members that are electrically connected to the other ends of the respective lead portions.

2. The image sensor module according to claim 1, wherein the transparent member is bonded to the top surface of the wafer through a bonding spacer.

3. The image sensor module according to claim 1, wherein the external connection members are solder balls which are electrically connected to the other ends of the respective lead portions.

4. The image sensor module according to claim 1 further comprising:
an IR cut-off portion formed on one surface of the transparent member, the IR cut-off portion serving to cut off long-wavelength infrared light included in light incident on the image sensor.

5. The image sensor module according to claim 1, wherein the encapsulation portion is formed of epoxy-based resin.
